(19) United States
(12) Patent Application Publication
(10) Pub. No.: US 2026/0299034 A1
(43) Pub. Date: Oct. 1, 2026

(54) CLOCK SYNCHRONIZATION CIRCUIT

(71) Applicant: Texas Instruments Incorporated, Dallas, TX (US)

(72) Inventors: David P. Magee, Allen, TX (US); Bassem IBRAHIM, Allen, TX (US); Jiayi LI, Allen, TX (US)

(73) Assignee: Texas Instruments Incorporated, Dallas, TX (US)

(21) Appl. No.: 19/312,448

(22) Filed: Aug. 28, 2025

Related U.S. Application Data
(60) Provisional application No. 63/780,837, filed on Mar. 31, 2025.

(51) Int. Cl. G01R 31/3842; G01R 31/36; H03L 7/085

(52) U.S. Cl. CPC G01R 31/3842; G01R 31/3648; H03L 7/085

(57) ABSTRACT

A method of clock synchronization includes generating, by a first device, a reference clock signal, and providing, by the first device, a reference count value based on counting cycles of the reference clock signal. The method also includes providing, by the first device, a command including the reference count value, and receiving, by a second device, the command. The method also includes generating, by the second device, a target clock signal, and determining, by the second device, a target count value based on the target clock signal. The method also includes adjusting, by the second device, a frequency and a phase of the target clock signal based on a difference between the reference count value and the target count value.

### CROSS-REFERENCE TO RELATED APPLICATIONS

This application claims priority to U.S. Provisional Application No. 63/780,837, filed Mar. 31, 2025, entitled “Clock Synchronization Using Digital Frequency and Phase Correction Methods,” which is hereby incorporated by reference.

### BACKGROUND

Many circuits include an oscillator to provide a clock signal. In a system that includes multiple oscillators, the clock signals generated by the oscillators may have mismatches in phase and/or frequency, which can impact the operation of the system.

### SUMMARY

In one example, a device includes a communication interface, a command processing circuit, a controllable clock source, a target phase counter, and a clock synchronization circuit. The command processing circuit has a command input and a reference phase output. The command input is coupled to the communication interface. The controllable clock source has a frequency control input and a clock output. The target phase counter has a clock input coupled to the clock output, and a target phase output. The clock synchronization circuit has a clock correction output coupled to the frequency control input. The clock synchronization circuit includes a phase difference circuit, a phase correction circuit, and a frequency correction circuit. The phase difference circuit has a reference phase input coupled to the reference phase output, a target phase input coupled to the target phase output, and a phase difference output. The phase correction circuit has an input coupled to the phase difference output, and a phase correction output coupled to the clock correction output. The frequency correction circuit has an input coupled to the phase difference output, and a frequency correction output coupled to the clock correction output.

In another example, an integrated circuit includes a communication interface, a controllable clock source, a counter, a command generation circuit, a command processing circuit, and a clock synchronization circuit. The controllable clock source has a frequency control input and a clock output. The counter has a clock input and a count output. The clock input is coupled to the clock output. The command generation circuit has a phase input and a command output. The phase input is coupled to the count output, and the command output is coupled to the communication interface. The command processing circuit has a command input, and a reference phase output. The command input is coupled to the communication interface. The clock synchronization circuit has a clock correction output coupled to the frequency control input. The clock synchronization circuit includes a phase difference circuit, a phase correction circuit, and a frequency correction circuit. The phase difference circuit has a reference phase input coupled to the reference phase output, a target phase input coupled to the count output, and a phase difference output. The phase correction circuit has an input coupled to the phase difference output, and a phase correction output coupled to the clock correction output. The frequency correction circuit has an input coupled to the phase difference output, and a frequency correction output coupled to the clock correction output.

In another example, a system includes a Device Under Test (DUT) monitoring device, first measurement device, and a second measurement device. The DUT monitoring device includes a stimulus generation circuit and an impedance spectroscopy circuit, and a current sense circuit. The stimulus generation circuit has a stimulus output. The impedance spectroscopy circuit has a first spectroscopy input, a second spectroscopy input, and an impedance spectroscopy output. The current sense circuit has a current sense output. The first measurement device includes a reference clock source, a counter, a synchronization command generation circuit, a first sampling circuit, and a first processing circuit. The reference clock source has a reference clock output. The counter has a first clock input and a count output. The first clock input is coupled to the reference clock output. The synchronization command generation circuit has a phase input, and a command output. The phase input is coupled to the count output. The first sampling circuit has a current sense input, a first sample output, and a second clock input. The second clock input is coupled to the reference clock output, and the current sense input is coupled to the current sense output. The first sampling circuit is configured to receive a current measurement signal at the current sense input and provide samples of the current measurement signal at the first sample output. The first processing circuit has a first processing input and a first processing output. The first processing input is coupled to the first sample output, and the first processing output is coupled to the first spectroscopy input. The first processing circuit is configured to provide first signals representing spectral components of the current measurement signal at the first processing output. The second measurement device includes a synchronization command processing circuit, a controllable clock source, a clock synchronization circuit, a second sampling circuit, and a second processing circuit. The synchronization command processing circuit has a command input coupled to the command output, and a reference phase output. The synchronization command processing circuit is configured to provide a reference count value at the reference phase output. The controllable clock source has a frequency control input and a first clock output. The controllable clock source is configured to generate a clock signal. The clock synchronization circuit is coupled to the synchronization command processing circuit. The clock synchronization circuit has a clock correction output coupled to the frequency control input. The clock synchronization circuit is configured to generate a clock control signal that controls a frequency of the clock signal based on the reference count value, and controls a phase of the clock signal based on the reference count value.

The second sampling circuit has a DUT input, a second sample output, and a third clock input. The third clock input is coupled to the first clock output. The second sampling circuit is configured to receive a voltage measurement signal at the DUT input and provide samples of the voltage measurement signal at the second sample output. The second processing circuit has a second processing input and a second processing output. The second processing input is coupled to the second sample output. The second processing output is coupled to the second spectroscopy input. The second processing circuit is configured to provide second signals representing spectral components of the voltage measurement signal at the second processing output.

In another example, a method includes generating, by a first device, a reference clock signal, and providing, by the first device, a reference count value based on counting cycles of the reference clock signal. The method also includes providing, by the first device, a command including the reference count value, and receiving, by a second device, the command. The method also includes generating, by the second device, a target clock signal, and determining, by the second device, a target count value based on the target clock signal. The method also includes adjusting, by the second device, a frequency and a phase of the target clock signal based on a difference between the reference count value and the target count value.

### BRIEF DESCRIPTION OF THE DRAWINGS

FIG. 1 is a block diagram of an example system for monitoring a state of a device under test (DUT).

FIGS. 2 and 3 are block diagrams of systems including devices coupled to one another for command communication.

FIG. 4 is a timing diagram showing example timing of reference and target clocks in a system.

FIG. 5 is a block diagram of an example system that provides clock synchronization via command transmission.

FIG. 6 is a block diagram of example circuitry of a target device for providing clock synchronization based on commands received from a reference device.

FIG. 7 is a block diagram of an example integrated circuit that includes battery monitoring circuitry and circuitry for clock synchronization via a communication interface.

FIG. 8 is a flow diagram of an example method of clock synchronization via a communication interface.

FIG. 9 is a flow diagram of an example method of generating synchronization commands in a reference device.

FIG. 10 is a flow diagram of an example method of clock synchronization in a target device.

FIG. 11 is a timing diagram showing synchronization communication between reference and target devices.

FIG. 12 is a diagram of an example phase synchronization command suitable for use in the system of FIG. 5.

FIG. 13 is a graph of example synchronization timing error with and without the synchronization described herein.

FIG. 14 is a block diagram of an example processor platform including processor circuitry structured to execute machine-readable instructions to implement the logic/functions depicted in the examples of FIGS. 5-10.

### DETAILED DESCRIPTION

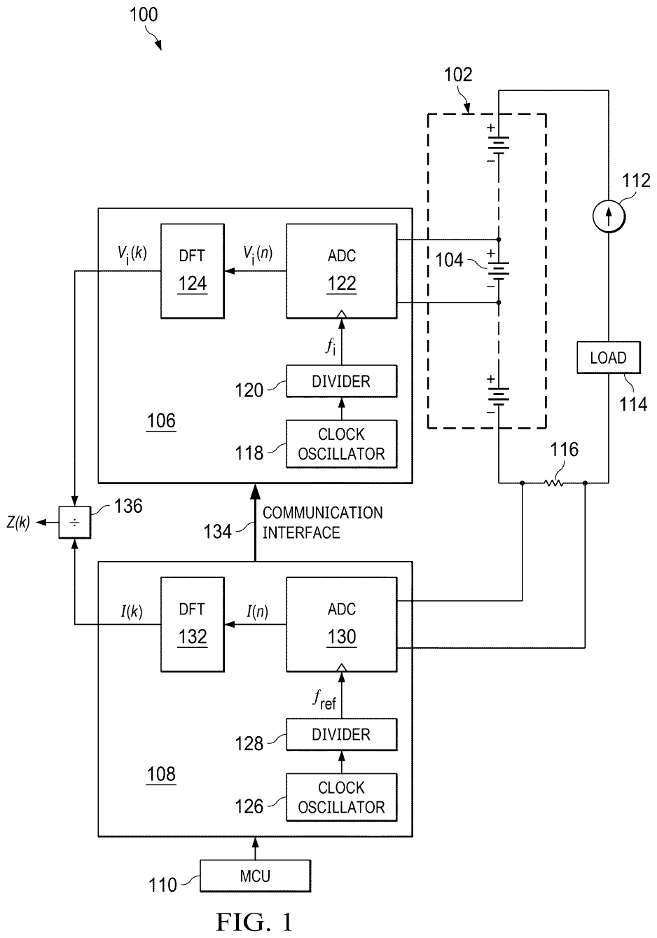

FIG. 1 is a block diagram of an example system 100 for monitoring a state of a DUT. The DUT may be a target device that is analyzed in the frequency domain using a spectroscopy method, such as impedance spectroscopy. Examples of the DUT can include a charge storage device (e.g., a battery, a capacitor, a super capacitor, etc.), a motor, a sensor, etc. In the example shown in FIG. 1, the system 100 includes a battery pack 102 as the DUT. In this example, the battery pack 102 contains multiple batteries, such as the battery 104, connected in series. In other examples, the battery pack 102 may contain a single battery 104. The battery pack 102 may power a vehicle (e.g., an electric or hybrid vehicle), a power tool, or other battery powered device. In other examples, the system 100 may include other types of DUTs.

In addition to the battery pack 102, the system 100 also includes a voltage measurement circuit 106, a current measurement circuit 108, a controller 110, an excitation current source 112, a load 114, and a sense resistor 116. The excitation current source 112, the load 114, and the sense resistor 116 are coupled in series between a positive terminal of the battery pack 102 and a negative terminal of the battery pack 102. The excitation current source 112 generates an excitation current for measuring the impedance of the battery 104. The current measurement circuit 108 and/or the voltage measurement circuit 106 are coupled to the controller 110 (e.g., via a serial communication bus). The controller 110 provides control information to, and retrieves status information from, the voltage measurement circuit 106 and the current measurement circuit 108. The voltage measurement circuit 106 can also be coupled to the current measurement circuit 108 via a communication interface 134. The communication interface 134 may be a serial bus that provides for exchange of information between the current measurement circuit 108 and the voltage measurement circuit 106.

The voltage measurement circuit 106 includes a clock oscillator 118, a frequency divider 120, an analog-to-digital converter (ADC) 122, and a discrete Fourier transform (DFT) circuit 124. The clock oscillator 118 generates a clock signal that is divided by the frequency divider 120 to produce a conversion clock that sets the timing of acquisition by the ADC 122. The ADC 122 samples the voltage of the battery 104 while the excitation current source 112 is generating the excitation current. The ADC 122 provides voltage measurement values representing the voltage samples to the DFT circuit 124, and the DFT circuit 124 transforms the voltage measurement values to the frequency domain, represented by Vᵢ(k) in FIG. 1.

The current measurement circuit 108 includes a clock oscillator 126, a frequency divider 128, an analog-to-digital converter (ADC) 130, and a discrete Fourier transform (DFT) circuit 132. The clock oscillator 126 generates a clock signal that is divided by the frequency divider 128 to produce a conversion clock that sets the timing of acquisition by the ADC 130. The ADC 130 samples the voltage across the sense resistor 116, which represents the current flowing through the sense resistor 116 and the battery pack 102, while the excitation current source 112 is generating the excitation current. The ADC 130 provides measurement values representing the current samples to the DFT circuit 132, and the DFT circuit 132 transforms the current measurement values to the frequency domain, represented by I(k) in FIG. 1.

The voltage measurement circuit 106 provides the voltage measurement values, and the current measurement circuit 108 provides the current measurement values, to an impedance computation circuit 136. The impedance computation circuit 136 may divide the voltage measurement values by the current measurement values at selected frequencies to provide an impedance spectroscopy analysis of the battery 104 at the selected frequencies. Information related to the state of the battery 104 can be determined based on the impedance spectroscopy analysis of the battery 104. For example, the internal temperature of the battery 104 may be determined based on the measured impedance spectroscopy analysis of the battery 104.

The accuracy of the impedance measurements provided by the system 100 is affected by the timing of the voltage and current sampling performed by the voltage measurement circuit 106 and the current measurement circuit 108. Differences in the sampling time of the voltage by the voltage measurement circuit 106 relative to the sampling time of the current by the current measurement circuit 108 can introduce misalignment in the sampling times of the voltage (by the voltage measurement circuit 106) and of the current (by the current measurement circuit 108). The misalignment can lead to non-correspondence between the voltage and current samples, which can reduce the accuracy of the impedance values, and reduce the accuracy of battery state information derived from the impedance values. The sampling by the voltage measurement circuit 106 and the current measurement circuit 108 may be synchronized for precise post-processing of data and for generating time aligned control commands. However, synchronization may be challenging, because the voltage measurement circuit 106 and current measurement circuit 108 have different clocks to determine the timing of local data measurements, where the clocks are based on the clock oscillator 118 and the clock oscillator 126. The frequencies of the clock oscillator 118 and clock oscillator 126 vary independently, with temperature and other factors. Calibration of the clock oscillator 118 and clock oscillator 126 may be insufficient to ensure the same clock source frequency during device operation due to temperature variations between devices and with time. Accordingly, the voltage measurement circuit 106 and the current measurement circuit 108 may not be properly synchronized, or may operate asynchronously with different clock frequencies and different phases, which may result in time misalignment between measurements that may introduce error in the impedance measurements.

In the system 100, the clock oscillator 118 and the clock oscillator 126, and the sampling of voltage and current by the voltage measurement circuit 106 and the current measurement circuit 108, can be synchronized to improve the accuracy of the impedance values. In the system 100, the clock oscillator 118 of the voltage measurement circuit 106 can be synchronized to the clock oscillator 126 of the current measurement circuit 108 by transferring synchronization information via the communication interface 134. The synchronization information can include phase information provided by the current measurement circuit 108, and transferred to the voltage measurement circuit 106 via the communication interface 134. The voltage measurement circuit 106 can apply the phase information to adjust the frequency and the phase of the clock signal generated by the clock oscillator 118 to match the frequency and phase of the clock signal generated by the clock oscillator 126 within an acceptable timing error (e.g. less than 3 micro-seconds), and synchronize sampling by the ADC 122 with sampling by the ADC 130.

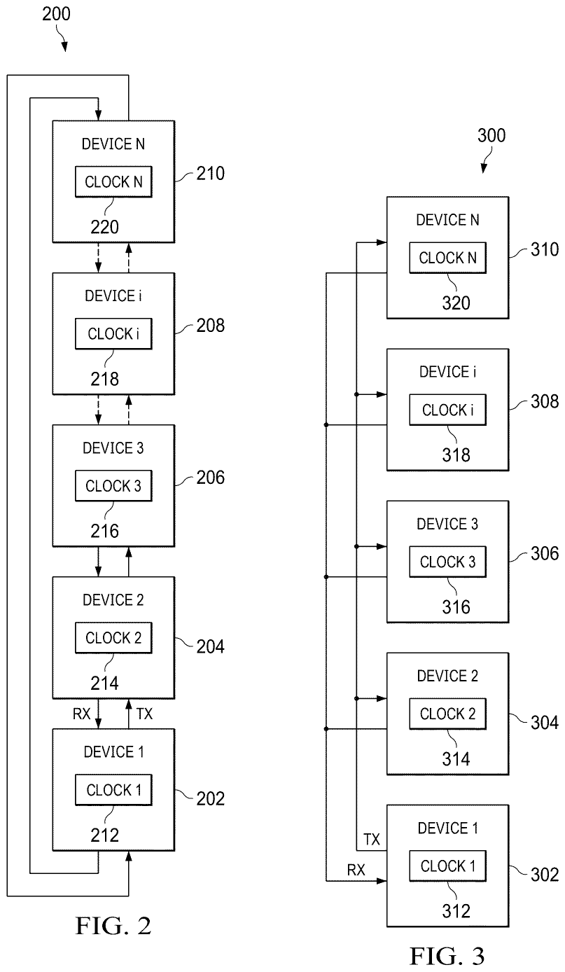

In examples of the system 100, the devices used to sample voltage and current can be connected in multiple topologies such as ring and bus topologies. FIG. 2 shows a system 200, including devices 202, 204, 206, 208, and 210 connected in a ring topology. In the ring topology of the system 200, commands are transferred serially from one device to another passing through intermediate devices. FIG. 3 shows a system 300, including devices 302, 304, 306, 308, and 310 connected in a bus topology. In the bus topology of the system 300, commands can be transferred from one reference device to all target devices in parallel. Examples of the system 100 may be implemented using bus or ring topologies.

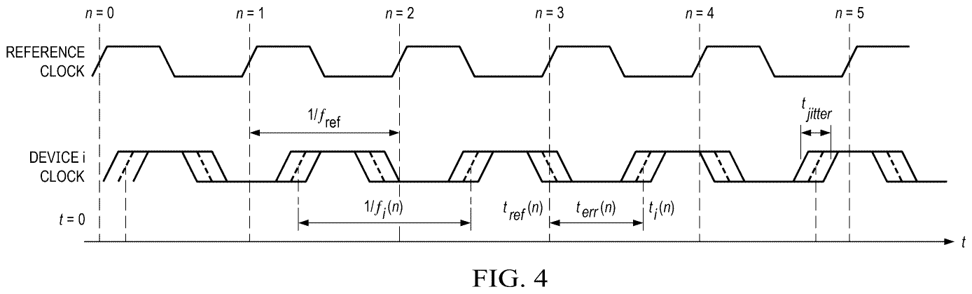

FIG. 4 is a timing diagram showing example timing of reference and target clocks in the system 100. In FIG. 4, the reference clock is labeled Reference Clock, and the target clock is labeled Device i Clock. The clock oscillator 126 provides the reference clock and the clock oscillator 118 provides the target clock. Considering frequency f_{ref} of the reference clock and frequency fᵢ(n) of the i^{th} target device (e.g., the voltage measurement circuit 106) at time sample n, the rising transition of each clock is defined as t_{ref}(n) and tᵢ(n) as shown in FIG. 4. The target device clock frequency includes cycle to cycle variation in frequency based on temperature variation and includes the effect of clock jitter tⱼᵢₜₜₑᵣ on the clock frequency. The time error between clocks is defined as:

$${t}_{err \_ i} ( n ) = {t}_{ref} ( n ) - {t}_{i} ( n ) \qquad ( 1 )$$

In the system 100, the clock oscillator 118 and the clock oscillator 126 are synchronized to minimize the sum of squared time error for the i^{th} target device during a measurement duration that is defined as

$${\sum }_{n = 1}^{N} {{t}_{err \_ i} ( n )}^{2} ,$$

where N the number of clock cycles of the measurement duration.

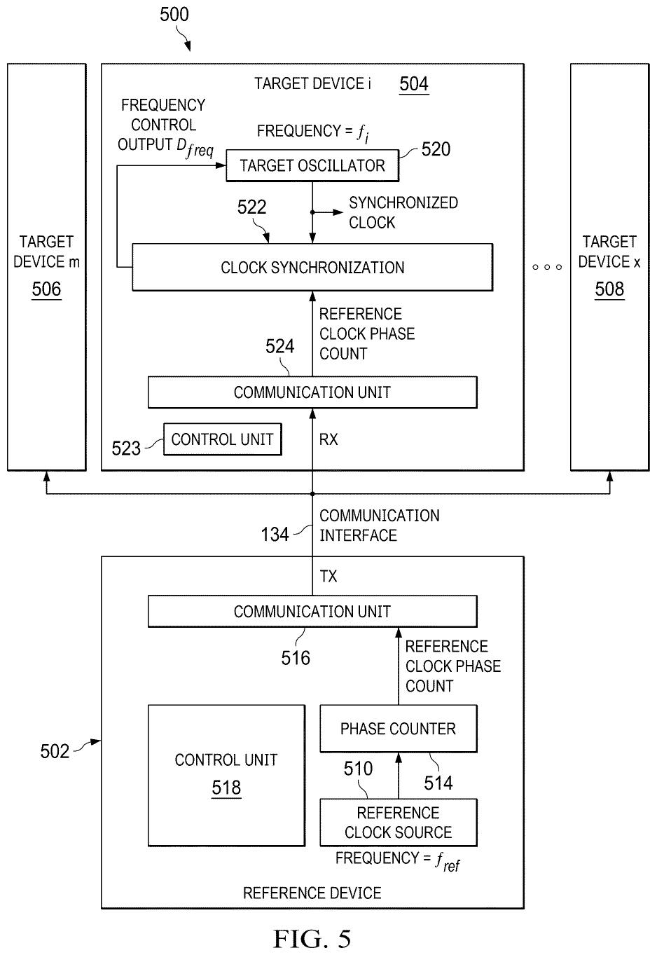

FIG. 5 is a block diagram of an example system 500 that provides clock synchronization via command transmission. The system 500 is an example of the system 100. The system 500 includes a reference device 502, and target devices 504, 506, and 508 coupled to the reference device 502 via a communication interface. Examples of the system 500 may include any number of target devices coupled to the reference device 502. The target device 506 and the target device 508 may include circuitry similar to that described with reference to the target device 504. Synchronization operations described with respect to the target device 504 are also applicable to the target device 506 and the target device 508.

The reference device 502 provides phase information to the target device 504 to synchronize the clock generated by the target device 504 to the clock generated by the reference device 502 by, for example, reducing the phase and/or frequency mismatches between the clocks. The reference device 502 includes a reference clock source 510, a phase counter 514, a communication unit 516, and a control unit 518. The reference clock source 510 generates a reference clock for timing operations of the reference device 502. An output of the reference clock source 510 (at which the reference clock is provided) is coupled to an input of the phase counter 514. Each reference device 502 can include an application specific integrated circuit (ASIC), or a programmable logic circuit, a programmable controller, etc., configured (e.g., by instructions) to control the operations of various components of the device. For example, control unit 518 of reference device 502 can be a programmable controller.

The phase counter 514 counts cycles of the reference clock within a selected phase determination time interval. An output of the phase counter 514 is coupled to an input of the communication unit 516. The phase counter 514 provides the count of reference clock cycles at the output as a reference clock phase count.

The communication unit 516 receives the reference clock phase count from the phase counter 514. The communication unit 516 includes a command generation circuit that generates synchronization commands based on the reference clock phase count. The communication unit 516 can periodically transmit the synchronization commands including the reference clock phase count to the target device 504 to adjust the frequency and phase of the target clock generated by the target device 504. For example, the communication unit 516 may broadcast a command including the reference clock phase count to the target devices 504, 506, and 508. The control unit 518 is coupled to the phase counter 514, and the communication unit 516 to control generation of the reference clock phase count, and the synchronization commands.

The target device 504 receives synchronization commands transmitted by the reference device 502, and applies the reference clock phase count to synchronize a target clock generated by the target device 504 to the reference clock generated by the reference device 502. The target device 504 includes a control unit 523, a communication unit 524, a clock synchronization circuit 522, and a target oscillator 520. An input of the communication unit 524 is coupled to an output of the communication unit 516 via the communication interface 134, and an output of the communication unit 524 is coupled to the clock synchronization circuit 522. The communication unit 524 receives the synchronization commands transmitted by the reference device 502. The communication unit 524 includes a command processing circuit that extracts the reference clock count from the synchronization commands, and provides the reference clock phase count to the clock synchronization circuit 522. Each target device, including target device 504, can include an application specific integrated circuit (ASIC), or a programmable logic circuit, a programmable controller, etc., configured (e.g., by instructions) to control the operations of various components of the device. For example, control unit 523 can be a programmable controller.

The clock synchronization circuit 522 includes phase and frequency synchronization circuitry. An output of the clock synchronization circuit 522 is coupled to an input of the target oscillator 520, and an input of the clock synchronization circuit 522 is coupled to an output of the target oscillator 520. The clock synchronization circuit 522 controls the frequency and phase of the target clock generated by the target oscillator 520 (shown in FIG. 5 as “synchronized clock”). The clock synchronization circuit 522 can generate phase and frequency correction signals based on a comparison of the reference clock phase count to a target clock phase count. The target clock phase count is a count of target clock cycles in the phase determination time interval. In some examples, various functions of the clock synchronization circuit 522 can be implemented using a programmable controller, a programmable logic circuit, an ASIC, etc.

In some examples, reference device 502 can be part of or include a measurement device (e.g., voltage measurement circuit 106, current measurement circuit 108, etc.), and target devices 506/508 can be part of or include another measurement device (e.g., voltage measurement circuit 106, current measurement circuit 108, etc.), the clock synchronization operations can be performed to reduce sampling time/frequency mismatches between voltage and current. In some examples, reference device 502/target devices 506/508 do not have sampling circuits (e.g., ADC 122/130). For example, reference device 502/target devices 506/508 can be part of controller 110 of FIG. 1. The clock synchronization operations can be performed to reduce time/frequency mismatches among, for example, the excitation current provided by excitation current source 112 and the sampling of the current and the voltage of battery 104 in response to the excitation current.

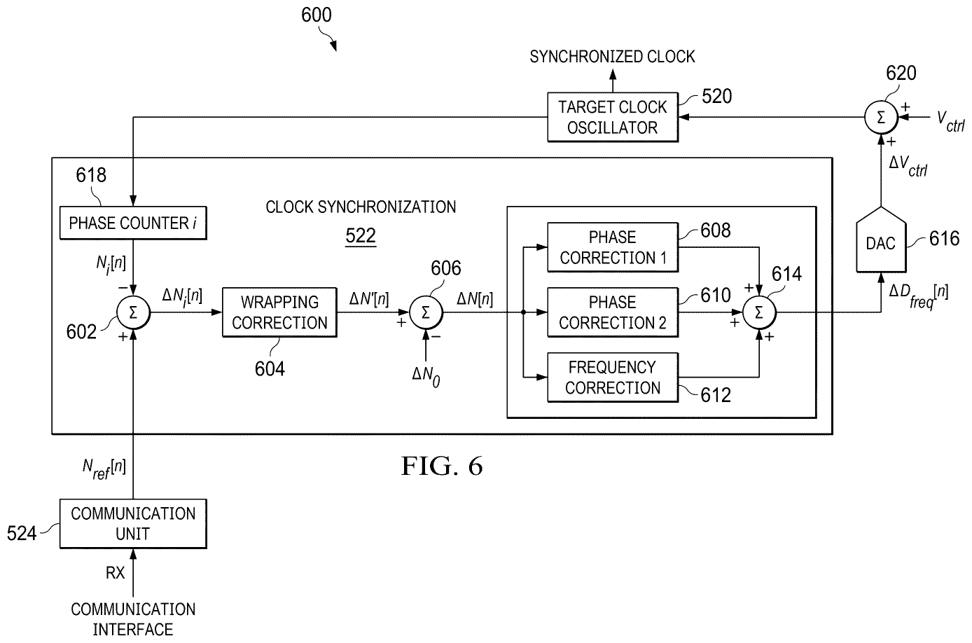

FIG. 6 is a block diagram of example circuitry 600 of the target device 504 for providing target clock synchronization based on commands received from the reference device 502. The circuitry 600 includes the target oscillator 520, the clock synchronization circuit 522, a digital-to-analog converter (DAC) 616, and a summing circuit 620. The communication unit 524 is shown for reference. The clock synchronization circuit 522 includes a phase counter 618, summing circuits 602, 606, and 614, a wrapping correction circuit 604, a phase correction 1 circuit 608, a phase correction 2 circuit 610, and a frequency correction circuit 612. The clock synchronization circuit 522 has a first input coupled to an output of the target oscillator 520 for reception of a synchronized clock signal generated by the target oscillator 520. The clock synchronization circuit 522 has a second input coupled to an output of the communication unit 524 for reception of the reference clock phase count (N_{ref}(n)). The clock synchronization circuit 522 has an output, at which a phase/frequency correction value (ΔD_{freq}(n)) is provided.

The phase counter 618 has an input coupled to the first input of the clock synchronization circuit 522 and an output coupled to the summing circuit 602. The phase counter 618 counts cycles of the synchronized clock provided by the target oscillator 520 within a selected phase determination time interval (e.g., the phase determination time interval used to acquire the reference clock phase count in the phase counter 514). The output of the phase counter 618 is coupled to the summing circuit 602. The phase counter 618 provides the count of synchronized clock cycles (Ni (n)) at the output as a target clock phase count.

The summing circuit 602 has a first input coupled to the output of the phase counter 618, a second input coupled to the second input of the clock synchronization circuit 522, and an output coupled to the wrapping correction circuit 604. The summing circuit 602 may be referred to as a phase comparator. The summing circuit 602 compares the reference and target phase counts and provides the difference of the reference and target phase counts (ΔNᵢ(n)) at its output.

The wrapping correction circuit 604 has an input coupled to the output of the summing circuit 602, and a wrap correction output coupled to the summing circuit 606. Because the phase counters 514 and 618 can wrap around at a maximum value (e.g., increment from a maximum value to a minimum value) equal to Nₗᵢₘᵢₜ, the wrapping correction circuit 604 corrects the difference value ΔNᵢ(n) to ΔNᵢ′(n) by subtracting Nₗᵢₘᵢₜ if

$$Δ {N}_{i} ( n ) \geq \frac{{N}_{limit}}{2}$$

and adding Nₗᵢₘᵢₜ if

$$Δ {N}_{i} ( n ) \leq - \frac{{N}_{limit}}{2} .$$

The corrected difference value ΔNᵢ′(n) is provided at the output of the wrapping correction circuit 604.

The summing circuit 606 sums the corrected difference value ΔNᵢ′(n) and an offset value to generate an offset adjusted difference value ΔN(n). The summing circuit 606 has a first input coupled to the wrap correction output of the wrapping correction circuit 604, and a second input for receiving an offset value ΔNₒ. The offset value ΔNₒ may represent a constant delay in the system 500, such as communication delay, command processing delay, etc., and may be provided at a time offset terminal. The summing circuit 606 has an output coupled to the phase correction 1 circuit 608, the phase correction 2 circuit 610, and the frequency correction circuit 612. The summing circuit 606 provides the offset adjusted difference value ΔN(n) at its output.

The phase correction 1 circuit 608, the phase correction 2 circuit 610, and the frequency correction circuit 612 compute phase and frequency corrections based on ΔN(n). The phase correction 1 circuit 608 has an input coupled to the output of the summing circuit 606, and an output coupled to the summing circuit 614. The phase correction 1 circuit 608 may compute a first phase correction value (also referred to as a phase correction signal) as a product of ΔN(n) and a gain value:

$${G}_{1} Δ N ( n ) \qquad ( 2 )$$

where G₁ is a selected gain value.

The phase correction 2 circuit 610 has an input coupled to the output of the summing circuit 606, and an output coupled to the summing circuit 614. Some examples of the clock synchronization circuit 522 may omit the phase correction 2 circuit 610. The phase correction 2 circuit 610 may compute a second phase correction value (also referred to as a phase correction signal) as a product of a gain value and a sum of difference values:

$${G}_{2} {\sum }_{k = 0}^{n} Δ N ( k ) \qquad ( 3 )$$

where G₂ is a selected gain value.

The frequency correction circuit 612 has an input coupled to the output of the summing circuit 606, and an output coupled to the summing circuit 614. The frequency correction circuit 612 may compute a frequency correction value (also referred to as a frequency correction signal) as a product of a gain value and a difference of successive difference values (a difference of two phase difference signals):

$${G}_{3} ( Δ N ( n ) - Δ N ( n - 1 ) ) \qquad ( 4 )$$

where G₃ is a selected gain value.

The summing circuit 614 sums the phase and frequency correction values provided by the phase correction 1 circuit 608, the phase correction 2 circuit 610, and the frequency correction circuit 612 to generate a clock correction value (also referred to as a clock correction signal) (ΔD_{freq}(n)). The summing circuit 614 has a first input coupled to the output of the phase correction 1 circuit 608, a second input coupled to the output of the phase correction 2 circuit 610, and a third input coupled to the output of the frequency correction circuit 612. The summing circuit 614 has an output, at which ΔD_{freq}(n) is provided, coupled to the DAC 616.

The DAC 616 converts ΔD_{freq}(n) to a voltage (ΔV_{ctrl}) for use in controlling the target oscillator 520. The DAC 616 has an input coupled to the output of the summing circuit 614, and an output coupled to the summing circuit 620.

The summing circuit 620 sums ΔV_{ctrl} and a nominal oscillator control voltage V_{ctrl} to produce a voltage for synchronizing the target oscillator 520 with the 510. V_{ctrl} may be provided by a reference voltage source (not shown) or any circuit suitable for providing a voltage for setting the frequency of the target oscillator 520. The summing circuit 620 has a first input coupled to the output of the DAC 616, a second input coupled to a nominal oscillator control voltage source or a nominal oscillator control voltage terminal, and an output coupled to the target oscillator 520.

By adjusting the control voltage provided to the target oscillator 520 based on the difference in reference and target clock phase count values, the clock synchronization circuit 522 can synchronize the clock provided by the target oscillator 520 with the reference clock source 510, with low timing error (e.g., less than 2 microseconds of error), using only the communication interface 134 to communicate synchronization information.

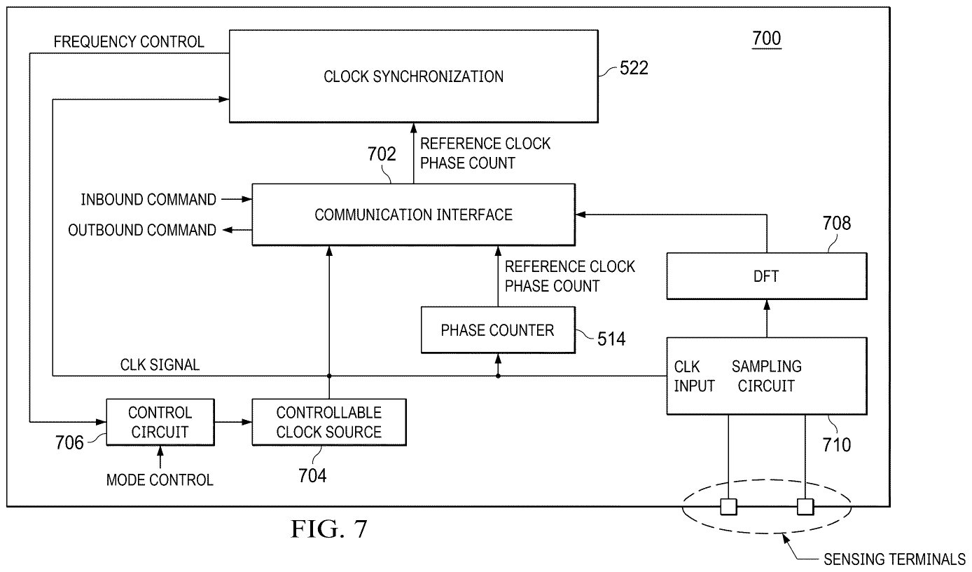

FIG. 7 is a block diagram of an example integrated circuit 700 that includes battery monitoring circuitry and circuitry for clock synchronization. The integrated circuit 700 is configurable to operate as a reference device that transmits clock synchronization commands, or as a target device that receives clock synchronization commands and synchronizes a target clock to a reference clock based on the received synchronization commands. The integrated circuit 700 includes the phase counter 514, the clock synchronization circuit 522, a communication interface 702, a controllable clock source 704, a mode control circuit 706, a DFT circuit 708, and a sampling circuit 710.

The sampling circuit 710 can include an ΔDC (such as the ΔDC 122 or 130 shown in FIG. 1) for digitizing a voltage or current measurement and a low pass filter to prevent aliasing in the voltage or current measurement. A sampling clock input of the sampling circuit 710 is coupled to a clock output of the controllable clock source 704. Sensing terminals of the sampling circuit 710 can be coupled to the battery 104 to sense a voltage signal, or the sense resistor 116 to sense a current signal, as shown in FIG. 1.

The DFT circuit 708 is a signal processing circuit and can be an example of the DFT circuit 124 or the DFT circuit 132 shown in FIG. 1. An input of the DFT circuit 708 is coupled to an output of the sampling circuit 710. The DFT circuit 708 transforms time-domain digital measurement values received from the sampling circuit 710 to frequency domain measurement values. An output of the DFT circuit 708 is coupled to the communication interface 702 for communication of the frequency domain measurement values to an external circuit that can compute impedance based on the frequency domain measurement values. In some examples, DFT circuit 708 can be a digital signal processor (DSP). In some examples, DFT circuit 708 can be part of an ASIC, a programmable logic circuit, etc., configured to perform the transform operations. The communication interface 702 can operate as the communication unit 516 or the communication unit 524 shown in FIG. 5. If the integrated circuit 700 is configured to operate as a reference device, then the communication interface 702 operates as the communication unit 516. If the integrated circuit 700 is configured to operate as a target device, then the communication interface 702 operates as the communication unit 524.

The controllable clock source 704 can operate as the reference clock source 510 or the target oscillator 520 shown in FIG. 5. If the integrated circuit 700 is configured as a reference device, then the controllable clock source 704 operates as the reference clock source 510. If the integrated circuit 700 is configured as a target device, then the controllable clock source 704 operates as the target oscillator 520.

The mode control circuit 706 provides frequency/phase control signals to the controllable clock source 704 if the integrated circuit 700 is operating as a target device. The mode control circuit 706 has a mode control input for receipt of a mode control signal that specifies whether the integrated circuit 700 is operating as reference device or a target device. For example, a first state of the mode control signal may specify that the integrated circuit 700 is to operate as a reference device, and a second state of the mode control signal may specify that the integrated circuit 700 is to operate as a target device. The mode control signal may be provided from a control register (not shown) of the integrated circuit 700. The mode control circuit 706 has a frequency control input coupled to an output of the clock synchronization circuit 522, and an output coupled to an input of the controllable clock source 704. The mode control circuit 706 can also control the operations of various components of the integrated circuit 700 such as the phase counter 514, the clock synchronization circuit 522, the communication interface 702, the DFT circuit 708, and the sampling circuit 710. In some examples, the mode control circuit 706 can be a programmable controller.

If the integrated circuit 700 is operating as a reference device, the mode control circuit 706 can provide a steady state signal to the controllable clock source 704. If the integrated circuit 700 is operating as a reference device, the mode control circuit 706 can also cause the communication interface 702 to operate as the communication unit 516, and can control the phase counter 514 to initiate generation of the reference clock phase count. If the integrated circuit 700 is operating as a target device, the mode control circuit 706 can cause the communication interface 702 to operate as the communication unit 524, and enable operation of the clock synchronization circuit 522.

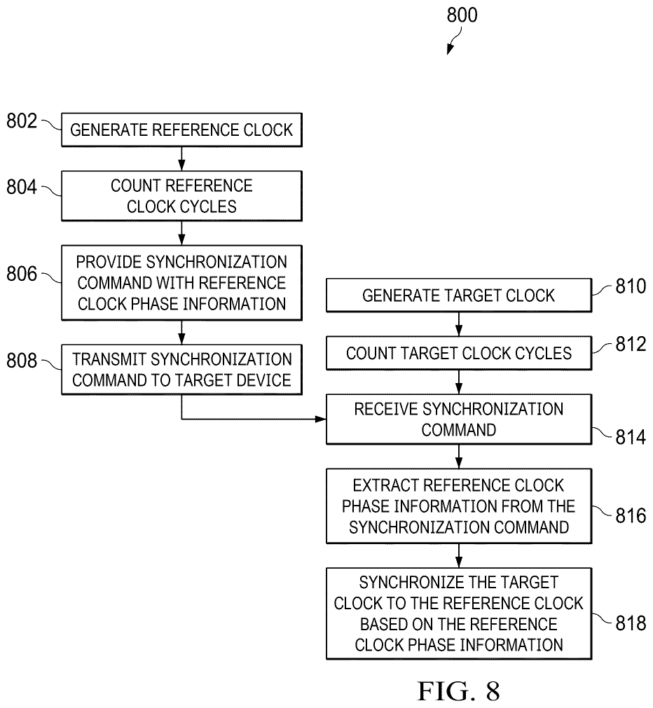

FIG. 8 is a flow diagram of an example method 800 of clock synchronization via a communication interface. Though depicted sequentially as a matter of convenience, at least some of the actions shown can be performed in a different order and/or performed in parallel. Additionally, some implementations may perform only some of the actions shown. Operations of the method 800 may be performed by an implementation of the system 500. For example, the operations of blocks 802 through 808 can be performed by the reference device 502, and operations of blocks 810 through 818 can be performed by the target device 504.

In block 802, the reference clock source 510 generates a reference clock. In block 810, the target oscillator 520 generates a target clock.

In block 804, the phase counter 514 counts cycles of the reference clock in a phase determination time interval. In block 812, the phase counter of the clock synchronization circuit 522 counts cycles of the target clock in the phase determination time interval.

In block 806, the reference device 502 (e.g., a command generation circuit of the reference device 502) generates a synchronization command that includes reference clock phase information. For example, the reference device 502 can generate a command that includes the count of cycles of the reference clock during the phase determination time interval (reference clock phase count), where the count of cycles is the reference clock phase information.

In block 808, the reference device 502 transmits the synchronization command to the target device 504.

In block 814, the target device 504 receives the synchronization command transmitted by the reference device 502.

In block 816, the target device 504 (e.g., a command processing circuit of the target device 504), extracts the reference clock phase information from the synchronization command. For example, the target device 504 can identify the synchronization command as including the reference clock phase count, and provide the reference clock phase count to the clock synchronization circuit 522.

In block 818, the target device 504 synchronizes the target clock to the reference clock based on the reference clock phase information provided by the reference device 502.

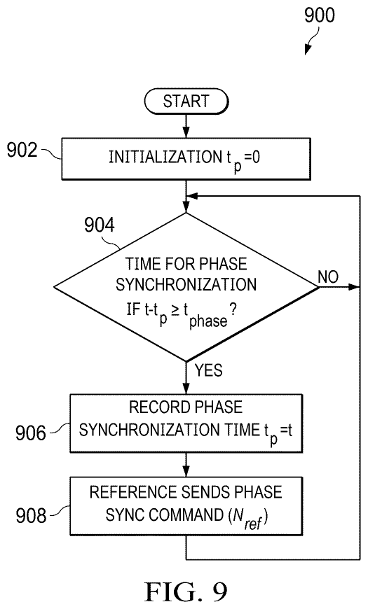

FIG. 9 is a flow diagram of an example method 900 of generating synchronization commands in the reference device 502. Though depicted sequentially as a matter of convenience, at least some of the actions shown can be performed in a different order and/or performed in parallel. Additionally, some implementations may perform only some of the actions shown.

In block 902, the reference device 502 (e.g., the control unit 518 of the reference device 502) initializes a phase synchronization time value.

In block 904, the reference device 502 (e.g., the control unit 518) determines whether it is currently time to provide phase synchronization to the target device 504. The determination is based on whether a phase synchronization time interval tₚₕₐₛₑ has elapsed from the last phase synchronization time tₚ. If the difference between current time (t) and the last phase synchronization tₚ is less than tₚₕₐₛₑ, then the control unit 518 determines that it is not time to provide phase synchronization to the target device 504, and the method 900 continues in block 904. Otherwise, if it is time to provide phase synchronization information to the target device 504, then the method 900 continues in block 906.

In block 906, the reference device 502 (e.g., the control unit 518) updates the latest time of phase synchronization tₚ to enable determination of a next time for phase synchronization.

In block 908, the reference device 502 (e.g., the control unit 518) generates a phase synchronization command and transmits the phase synchronization command to the target device 504. Generation of the phase synchronization command can include the control unit 518 retrieving a reference clock phase count from the phase counter 514, and providing the reference clock phase count to the communication unit 516, which can then insert the reference phase count into the phase synchronization command and transmit the phase synchronization command. The method 900 continues in block 904.

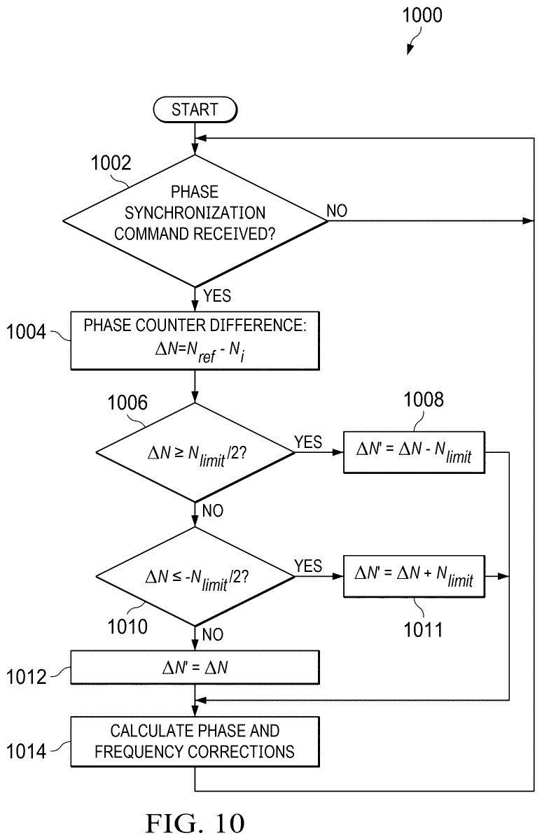

FIG. 10 is a flow diagram of an example method 1000 of phase and frequency synchronization in the target device 504. Though depicted sequentially as a matter of convenience, at least some of the actions shown can be performed in a different order and/or performed in parallel. Additionally, some implementations may perform only some of the actions shown.

In the system 500, the clock phase is captured in each device by a phase counter that resets at the beginning of a measurement and increments at each clock cycle. At a phase synchronization interval tₚₕₐₛₑ, the reference device 502 samples its phase counter N_{ref} and transmits this value in a phase synchronization command to the target device 504. When the target device 504 receives the phase synchronization command, it samples its phase counter Nᵢ and compare the values of its phase counter and the reference phase counter through a digital comparator (e.g., the summing circuit 602).

In block 1002, the target device 504 (e.g., control unit 523) determines whether a phase synchronization command has been received from the reference device 502. If a phase synchronization command has not been received, then the method 1000 continues in block 1002. If a phase synchronization command has been received, then the method 1000 continues in block 1004.

In block 1004, the target device 504 (e.g., control unit 523) extracts the reference clock phase count N_{ref} from the phase synchronization command and provides the reference clock phase count to the clock synchronization circuit 522. The clock synchronization circuit 522 also retrieves a target clock phase count value Nᵢ from a target phase counter of the target device 504, and subtracts the target clock phase count from the reference clock phase count to produce a phase difference value (also referred to as a phase difference signal) (ΔN).

The reference and target phase counters can wrap at a value Nₗᵢₘᵢₜ. The operations of blocks 1006 through 1012 correct for such counter wrap. In block 1006, the target device 504 (e.g., the wrapping correction circuit 604) determines whether the phase difference value is greater than or equal to half of Nₗᵢₘᵢₜ. If the phase difference value is less than half of Nₗᵢₘᵢₜ then the method 1000 continues in block 1010, otherwise the method 1000 continues in block 1008.

In block 1008, the target device 504 (e.g., the wrapping correction circuit 604) subtracts Nimit from the phase difference value to produce an adjusted phase difference value (ΔN′).

In block 1010, the target device 504 (e.g., the wrapping correction circuit 604) determines whether the phase difference value is less than or equal to half of −Nₗᵢₘᵢₜ. If the phase difference value is greater than half of −Nₗᵢₘᵢₜ then the method 1000 continues in block 1012, otherwise the method 1000 continues in block 1011.

In block 1011, the target device 504 (e.g., the wrapping correction circuit 604) adds Nₗᵢₘᵢₜ to the phase difference value to produce an adjusted phase difference value (ΔN′).

In block 1012, the target device 504 (e.g., the wrapping correction circuit 604) sets the adjusted phase difference value (ΔN′) to be equal to the phase difference value (ΔN).

In block 1014, the target device 504 (e.g., the phase correction 1 circuit 608, the phase correction 2 circuit 610, and the frequency correction circuit 612) provides the phase and frequency control signals as shown in equations (1), (2), and (3).

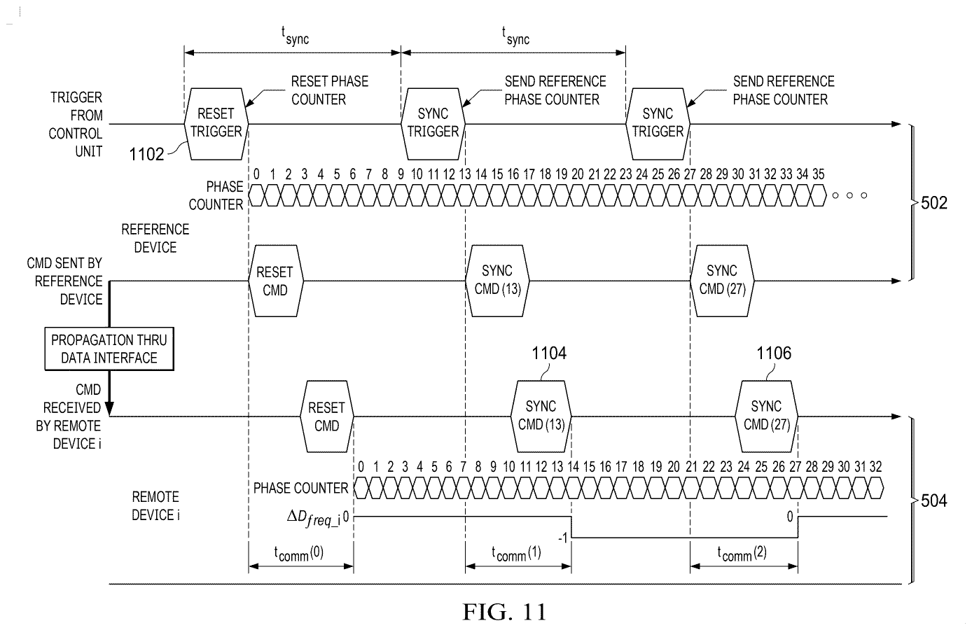

FIG. 11 is a timing diagram showing phase synchronization communication between the reference device 502 and the target device 504. FIG. 11 shows, in the reference device 502, triggering of phase synchronization commands at interval t_{sync}, transmission of phase synchronization commands, and reference phase counter state. In the target device 504, FIG. 11 shows reception of phase synchronization commands, target phase counter state, and ΔD_{freq} based on comparison of reference and target phase counts.

In FIG. 11, the clock synchronization sequence can start by the control unit 518 in the reference device 502 triggering the phase synchronization at a t_{sync} interval. The reference device 502 responds to the phase synchronization triggers from the control unit 518 by generating and sending phase synchronization commands that include reference clock phase count. The reset trigger 1102 leads to a counter reset command (a reset count command to reset the phase counters) followed by generation and transmission of phase synchronization commands that include the reference clock phase count. In the example shown in FIG. 11, the phase synchronization commands 1104 and 1106 include phase counts of 13 and 27, respectively. The target device 504 receives the phase synchronization command after the data interface delay of t_{comm}, which is the delay between clocks after synchronization. This data interface delay is a deterministic delay that can be determined and compensated for in data post-processing. The corresponding target device phase counts after receiving the phase synchronization commands are 14 and 27, respectively. This phase counter difference after the phase synchronization command 1104 is 1, which indicates a phase and time error between the reference and device clock. Therefore, a change in the target device frequency ΔD_{freq} is required to reduce the phase and time error. Once the phase counter values match, no further change in the target device oscillator frequency is required. This condition means that the phase and time error is minimum between the reference and target device clocks and clock synchronization has been achieved between them.

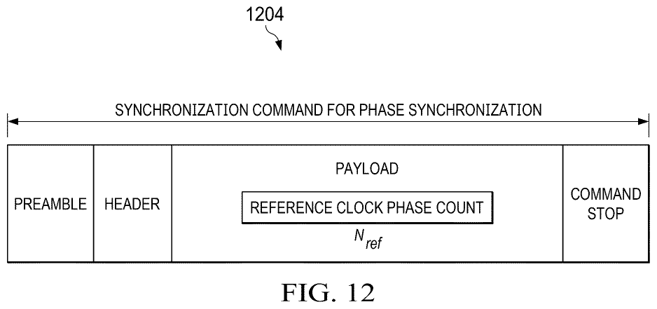

FIG. 12 is a diagram of an example phase synchronization command sent by the reference device 502 to the target device 504. The command 1204 of FIG. 12 is an example phase synchronization command. The command 1204 starts with a preamble for synchronization between transmitting and receiving communication units in the reference and target devices, respectively. The next portion of the command is the header which can include an identifier for the command type, followed by the payload that includes the required information to be transmitted. In the command 1204, the payload includes the reference phase count for the phase synchronization command. The reference phase clock count can be represented by a binary number having a predetermined set of bits. A command parser (e.g., part of communication unit 524/communication interface 702) can parse the command based on the command type indicated in the header to extract the set of bits representing the reference phase count. Finally, the command 1204 ends with a command stop field that identifies the end of the synchronization command. For improved reliability of the communication channel, the command might also be encrypted using error correction codes.

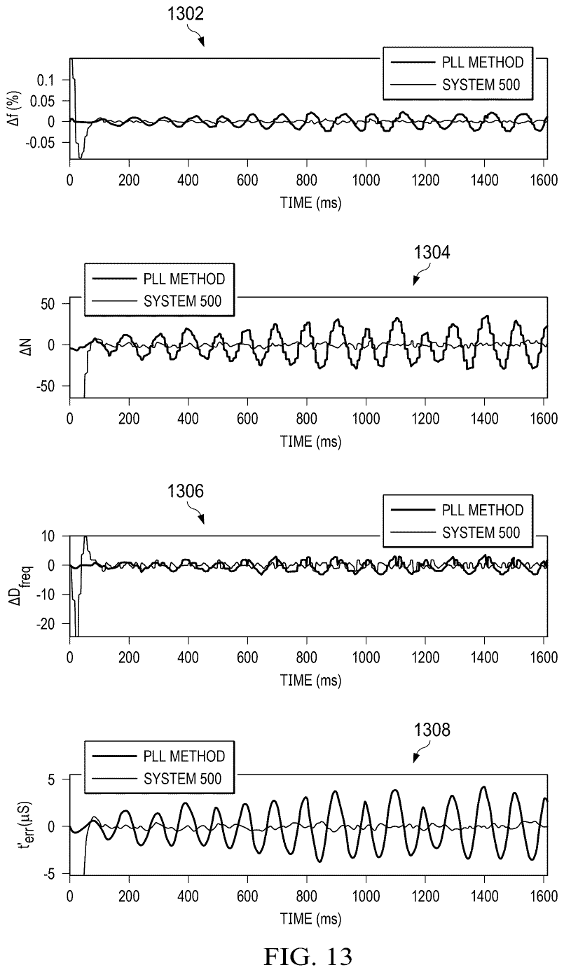

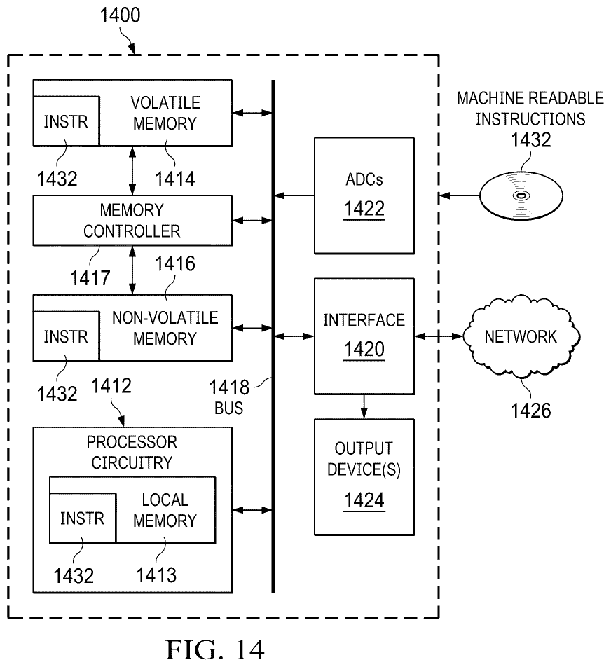

FIG. 13 is a graph of example synchronization timing error using the synchronization method implemented in the system 500 and a synchronization method using a periodic phase-locked loop (PLL) synchronization (PLL method). FIG. 14 shows a comparison of clock frequency error (Δf), phase counter difference (ΔN), clock correction value (ΔD_{freq}), and time error \acute{t}ₑᵣᵣ between the method used by the system 500 and the PLL method. The graph 1302 shows that frequency variation in the system 500 is significantly lower than with the PLL method. The graph 1304 shows that difference in reference and target phase count values is significantly lower in the system 500 than with the PLL method. The graph 1306 shows that variation of the clock control signal is greater using the PLL method than in the system 500. The graph 1308 shows that \acute{t}ₑᵣᵣ is about 5 microseconds using the PLL method, and less than 1 microsecond in the system 500.

FIG. 14 is a block diagram of an example processor platform 1400 including processor circuitry structured to execute machine-readable instructions to implement the logic/functions depicted in the examples of FIGS. 5-10. For example, processor platform 1400 can be part of or include reference device 502 and target devices 504, 506, and 508 of FIG. 5, and integrated circuit 700 of FIG. 7.

Processor platform 1400 of the illustrated example can include processor circuitry 1412. The processor circuitry 1412 of the illustrated example includes hardware. For example, processor circuitry 1412 can be implemented by one or more integrated circuits, logic circuits, FPGAs, microprocessors, Central Processing Units (CPUs), Graphical Processing Units (GPUs), Digital Signal Processors (DSPs), and/or microcontrollers from any desired family or manufacturer. Processor circuitry 1412 can be implemented by one or more semiconductor-based (e.g., silicon-based) devices. In some examples, processor circuitry 1412 can implement the control units 518, 523, phase synchronization circuit 528, mode control circuit 706, DFT circuit 708, etc.

Processor circuitry 1412 of the illustrated example can include a local memory 1413 (e.g., a cache, registers, etc.). Processor circuitry 1412 of the illustrated example is in communication with a computer-readable storage device such as a main memory including a volatile memory 1414 and a non-volatile memory 1416 by a bus 1418. The volatile memory 1414 can be implemented by, for example, Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1416 may be implemented by programmable read-only memory, flash memory and/or any other desired type of non-volatile memory device. Access to the volatile memory 1414 and the non-volatile memory 1416 of the illustrated example can be controlled by a memory controller 1417.

The processor platform 1400 of the illustrated example also includes interface circuitry 1420. The interface circuitry 1420 may be implemented by hardware in accordance with any type of interface standard, such as an Inter-Integrated Circuit (I2C) interface, a Serial Peripheral Interface (SPI), an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface. The interface circuitry 1420 may include or may be part of communication units 516 and 524.

In the illustrated example, one or more input ADCs 1422 are connected to bus 1418. The ADCs 1422 can convert analog signals to digital signals for processing by the processor circuitry 1412. ADCs 1422 can represent sampling circuit 710.

One or more output devices 1424 can be connected to the interface circuitry 1420 of the illustrated example. The output device(s) 1424 can include circuits such as driver circuits.

Machine-readable instructions 1432 can be stored in volatile memory 1414 and/or non-volatile memory 1416. Upon execution by the processor circuitry 1412, the machine-readable instructions 1432 cause the processor platform 1400 to perform any or all of the functionality described herein attributed to the reference device 502, target devices 504, 506, and 508, integrated circuit 700, and methods 800, 900, and 1000.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Modifications are possible in the described embodiments, and other embodiments are possible, within the scope of the claims.

What is claimed is:

1. A device comprising:
a communication interface;
a command processing circuit having a command input and a reference phase output, the command input coupled to the communication interface;
a controllable clock source having a frequency control input and a clock output;
a target phase counter having a clock input coupled to the clock output, and a target phase output; and
a clock synchronization circuit having a clock correction output coupled to the frequency control input, the clock synchronization circuit including:
a phase difference circuit having a reference phase input coupled to the reference phase output, a target phase input coupled to the target phase output, and a phase difference output;
a phase correction circuit having an input coupled to the phase difference output, and a phase correction output coupled to the clock correction output; and
a frequency correction circuit having an input coupled to the phase difference output, and a frequency correction output coupled to the clock correction output.

2. The device of claim 1, wherein:
the command processing circuit is configured to:
receive a command including a reference count value; and
provide the reference count value at the reference phase output;
the target phase counter is configured to provide a target count value at the target phase output; and
the phase difference circuit includes a phase comparator configured to generate a phase difference signal based on a comparison between the reference count value and the target count value.

3. The device of claim 2, wherein the phase correction circuit is configured to: generate a first phase correction signal as a product of the phase difference signal and a first gain value.

4. The device of claim 3, wherein the frequency correction circuit is configured to generate a frequency correction signal as a product of a third gain value and a difference of two phase difference signals.

5. The device of claim 4, wherein the clock synchronization circuit includes a summing circuit configured to generate a clock correction signal as a sum the first phase correction signal and the frequency correction signal, and provide the clock correction signal at the clock correction output.

6. The device of claim 4, wherein the phase correction circuit is configured to generate a second phase correction signal as product of a second gain value and a sum of multiple phase difference signals.

7. The device of claim 6, wherein the clock synchronization circuit includes a summing circuit configured to generate a clock correction signal as a sum the first phase correction signal, the second phase correction signal, and the frequency correction signal, and provide the clock correction signal at the clock correction output.

8. The device of claim 1, further comprising:
a digital-to-analog converter (DAC) having an input coupled to the clock correction output, and an output;
a summing circuit having a first input coupled to the output of the DAC, a second input coupled to nominal control voltage terminal; and an output coupled to the frequency control input.

9. The device of claim 1, wherein the clock synchronization circuit includes a wrapping correction circuit having an input coupled to the phase difference output, and a wrap correction output coupled to the input of the phase correction circuit and the input of the frequency correction circuit.

10. The device of claim 9, wherein the clock synchronization circuit includes a summing circuit having a first input coupled to the wrap correction output, a second input coupled to a time offset terminal, and an output coupled to the input of the phase correction circuit and the input of the frequency correction circuit.

11. The device of claim 1, wherein the communication interface, the command processing circuit, and the clock synchronization circuit are part of an integrated circuit, and the integrated circuit further comprising:
a sampling circuit having a sense input, a sample output, and a sampling clock input, the sampling clock input coupled to the clock output, the sampling circuit configured to receive a measurement signal at the sense input and provide samples of the measurement signal at the sample output; and
a processing circuit having a processing input and a processing output, the processing input coupled to the sample output, the processing circuit configured to provide signals representing spectral components of the measurement signal at the processing output.

12. The device of claim 11, wherein the measurement signal includes at least one of: a current signal through a device under test (DUT), or a voltage signal across the DUT.

13. The device of claim 12, wherein the DUT is a battery.

14. An integrated circuit comprising:
a communication interface;
a controllable clock source having a frequency control input and a clock output;
a counter having a clock input and a count output, the clock input coupled to the clock output;
a command generation circuit having a phase input and a command output, the phase input coupled to the count output, and the command output coupled to the communication interface;
a command processing circuit having a command input, and a reference phase output, the command input coupled to the communication interface; and
a clock synchronization circuit having a clock correction output coupled to the frequency control input, the clock synchronization circuit including:
a phase difference circuit having a reference phase input coupled to the reference phase output, a target phase input coupled to the count output, and a phase difference output;
a phase correction circuit having an input coupled to the phase difference output, and a phase correction output coupled to the clock correction output; and
a frequency correction circuit having an input coupled to the phase difference output, and a frequency correction output coupled to the clock correction output.

15. The integrated circuit of claim 14, further comprising a mode control circuit having a mode control input, the mode control circuit configured to:
responsive to the mode control input having a first state, cause the command generation circuit to:
receive a count value at the phase input;
transmit a command including the count value at the command output via the communication interface; and
responsive to the mode control input having a second state:
cause the command processing circuit to receive a command including a reference count value and provide the reference count value at the reference phase output;
cause the clock synchronization circuit to provide a frequency correction signal at the clock correction output based on the reference count value; and
cause the controllable clock source to provide a clock signal at a second clock output based on the frequency correction signal.

16. The integrated circuit of claim 14, further comprising
a sampling circuit having a sense input, a sample output, and a sampling clock input, the sampling clock input coupled to the clock output, the sampling circuit configured to receive a measurement signal at sense input and provide samples of the measurement signal at the sample output; and
a signal processing circuit having a processing input and a processing output, the processing input coupled to the sample output, the signal processing circuit configured to provide signals representing spectral components of the measurement signal at the processing output.

17. The integrated circuit of claim 16, wherein the measurement signal includes at least one of: a current signal through a device under test (DUT), or a voltage signal across the DUT.

18. The integrated circuit of claim 17, wherein the DUT is a battery.

19. A system comprising:
a Device Under Test (DUT) monitoring device including:
a stimulus generation circuit having a stimulus output;
an impedance spectroscopy circuit having a first spectroscopy input, a second spectroscopy input, and an impedance spectroscopy output;
a current sense circuit having a current sense output;
a first measurement device including:
a reference clock source having a reference clock output;
a counter having a first clock input and a count output, the first clock input coupled to the reference clock output;
a synchronization command generation circuit having a phase input, and a command output, the phase input coupled to the count output;
a first sampling circuit having a current sense input, a first sample output, and a second clock input, the second clock input coupled to the reference clock output, the current sense input coupled to the current sense output, and the first sampling circuit configured to receive a current measurement signal at the current sense input and provide samples of the current measurement signal at the first sample output; and
a first processing circuit having a first processing input and a first processing output, the first processing input coupled to the first sample output, the first processing output coupled to the first spectroscopy input, and the first processing circuit configured to provide first signals representing spectral components of the current measurement signal at the first processing output; and
a second measurement device including:
a synchronization command processing circuit having a command input coupled to the command output, and a reference phase output, the synchronization command processing circuit configured to provide a reference count value at the reference phase output;
a controllable clock source having a frequency control input and a first clock output, the controllable clock source configured to generate a clock signal;
a clock synchronization circuit coupled to the synchronization command processing circuit, the clock synchronization circuit having a clock correction output coupled to the frequency control input, the clock synchronization circuit configured to generate a clock control signal that controls a frequency of the clock signal based on the reference count value, and controls a phase of the clock signal based on the reference count value;
a second sampling circuit having a DUT input, a second sample output, and a third clock input, the third clock input coupled to the first clock output, and the second sampling circuit configured to receive a voltage measurement signal at the DUT input and provide samples of the voltage measurement signal at the second sample output; and
a second processing circuit having a second processing input and a second processing output, the second processing input coupled to the second sample output, the second processing output coupled to the second spectroscopy input, and the second processing circuit configured to provide second signals representing spectral components of the voltage measurement signal at the second processing output.

20. The system of claim 19, wherein the DUT is a battery.

21. A method comprising:
generating, by a first device, a reference clock signal;
providing, by the first device, a reference count value based on counting cycles of the reference clock signal;
providing, by the first device, a command including the reference count value;
receiving, by a second device, the command;
generating, by the second device, a target clock signal;
determining, by the second device, a target count value based on the target clock signal; and
adjusting, by the second device, a frequency and a phase of the target clock signal based on a difference between the reference count value and the target count value.
